(19) United States
(12) Patent Application Publication
(10) Pub. No.: US 2014/0220771 A1
(43) Pub. Date: Aug. 7, 2014

(54) WORM MEMORY DEVICE AND PROCESS OF MANUFACTURING THE SAME

(71) Applicant: NATIONAL TSING HUA UNIVERSITY, Hsinchu City (TW)

(72) Inventors: Yung-Hsien Wu, Hsinchu City (TW); Min-Lin Wu, Hsinchu City (TW)

(73) Assignee: NATIONAL TSING HUA UNIVERSITY, Hsinchu City (TW)

(21) Appl. No.: 13/759,279

(22) Filed: Feb. 5, 2013

(51) Int. Cl. H01L 21/283

(52) U.S. Cl. CPC H01L 21/283; B82Y 40/00
USPC 438/597; 977/890

(57) ABSTRACT

A process of manufacturing a Write-Once-Read-Many-times memory, at least includes the following steps: (A) providing a substrate as a lower electrode; (B) depositing a first oxide layer on the substrate; (C) depositing at least one or more silicon/germanium (Si/Ge) layers on the first oxide layer; (D) depositing a second oxide layer on the at least one or more Si/Ge layers; (E) carrying out a rapid thermal annealing to form SiGe nanocrystals embedded in the first dioxide layer and the second oxide layer; and (F) depositing a conductive layer on the second oxide layer as an upper electrode. The SiGe nanocrystals embedded in the Al₂O₃ bilayer as the active layer of the WORM memory offers high thermal stability, so that low operating voltage, fast writing, ideal reading durability, persistence at high temperature, and the highly reliable memory performance for effectively reading data at high temperature can be achieved.

### BACKGROUND OF THE INVENTION

1. Field of the Invention

The present invention relates to a Write-Once-Read-Many-times (WORM) memory device and a process of manufacturing the same. Particularly it relates to a WORM memory device and a process of manufacturing the same in which by depositing Al₂O₃-bilayer sandwiched Si/Ge and subsequently performing a thermal annealing process, a SiGe nano-crystal structure is formed. More particularly, it relates to a WORM memory device and a process of manufacturing the same in which by adjusting the thickness of each layer of the Si/Ge structure, the process of manufacturing a WORM memory device and the WORM can be rendered a reliable way to realize ideal SiGe nanocrystals in a dielectric to be embedded in Al₂O₃.

2. Description of Related Art

A Write-Once-Read-Many-times (WORM) memory system is a data storage media that allows messages to be written once but be read many times. This type of memory has been widely used in applications whose messages cannot be changed or destroyed, such as electronic voting, accident records, un-editable database, and tags of a radio frequency identification (RFID) system. Booming in development of various applications, a variety of materials has been proposed in the literature to form an active layer of a memory. Organic or polymer materials have attracted strong interest because of being able to a large-area WORM memory array in cost effective way. However, these promising materials cannot be compatible with existing inorganic ultra-large scale integration (ULSI) for technical needs at this stage. Based on this requirement, aluminum nanocrystals embedded in the aluminum nitride (AlN) or aluminum oxide (Al₂O₃) have been reported to be conducive to the realization of the nanocrystals based WORM memory. However, the WORM device has also been reported that the nanocrystals formed by Al-rich Al₂O₃ are randomly distributed in the Al₂O₃. Al₂O₃, however, is highly defective. Because charges may be stored in the nanocrystals and/or Al₂O₃ which has defects in the vicinity of the Si substrate. The stored charges are limited by the loss due to high temperatures, which may lead to deterioration of durability. In addition, because of the low melting point of Al, the density and shape of Al nanocrystals can be changed by high-temperature thermal treatment usually used in the ULSI technology, so that the performance of the device may be affected.

In fact, due to small energy gaps, a germanium (Ge) nanocrystals-based flash memory has been proved to have an ideal durable feature, compared to silicon nanocrystals-based flash memory. Even although Ge nanocrystals are easily formed in a silicon oxide (SiO₂) substrate. Whereas, it must reduce the operating voltage for nucleation in a dielectric material of high dielectric constant (high-K). Such a need is extremely difficult to meet, unless using a special process such as pulsed laser deposition (PLD). Therefore, the conventional means cannot meet the requirement for the users in actual use.

For this reason, the inventors has studied and proceeded in-depth discussion, and actively seek approaches for many years engaged in the research and experiences of related industries and manufacturing. After long-term research and efforts in development, the inventors has finally the successfully developed this invention ‘a Write-Once-Read-Many-times memory device and a process of manufacturing the same’ which overcomes the shortages in the prior art.

### SUMMARY OF THE INVENTION

A main purpose of this invention is to provide a process of manufacturing a WORM memory device and a WORM memory device thereof, which overcome the problems in the prior art. By depositing Al₂O₃-bilayer sandwiched Si/Ge and subsequently performing a thermal annealing process, a SiGe nano-crystal structure is formed. By means of adjusting the thickness of each layer of the Si/Ge structure, the process of manufacturing a WORM memory device and the WORM can be rendered a reliable way to realize ideal SiGe nanocrystals in a dielectric to be embedded in Al₂O₃.

It is another object of the invention to provide a WORM memory device which can be stored in the nanocrystals via holes programming at a negative pulse. The current level can increase by 10⁴ times by means of application of −10V/1 s pulse. Even at −5V/1 μs pulse, it still can obtain a large enough current ratio to distinguish the logic states and have good memory characteristics.

It is still another object of the invention to provide a WORM memory device in which by the use of SiGe nanocrystals embedded in the Al₂O₃ bilayer as the active layer of the WORM memory to offer high thermal stability, it can achieve the low operating voltage, the fast writing, the ideal reading durability, and the persistence at high temperature, and the highly reliable memory performance for effectively reading data at high temperature.

It is still another object of the invention to provide a WORM memory device which has a reading life up to 10⁵ times and superior durability of over 100 years and is suitable for high-performance storage applications.

In order to achieve the above and other objectives, the WORM memory device and the process of manufacturing the same at least include the following steps: (A) providing a substrate as a lower electrode; (B) depositing a first oxide layer on the substrate; (C) depositing at least one or more silicon/germanium (Si/Ge) layers on the first oxide layer; (D) depositing a second oxide layer on the at least one or more Si/Ge layers; (E) caning out a rapid thermal annealing (RTA); oxygen (O₂) is diluted with nitrogen (N₂) with the reaction at 600-800° C. for 80 to 100 seconds; a Si/Ge layer forms a SiGe nano-crystal structure (SiGe nanocrystals) embedded in the first dioxide layer and the second oxide layer; and (F) depositing a conductive layer on the second oxide layer as an upper electrode.

In one embodiment of the invention, a step of depositing a protective layer on the conductive layer is further included.

In one embodiment of the invention, the substrate is a Si substrate.

In one embodiment of the invention, the first dioxide layers and the second oxide layer are of high dielectric constant (high-k) non-crystalline material, and can be Al₂O₃.

In one embodiment of the invention, the first oxide layer has the thickness ranging from 5.0 to 7.4 nanometer (nm).

In one embodiment of the invention, the Si/Ge layer is a repeated structure consisting by a Si layer and a Ge layer and the repeated structure is deposited for at least once.

In one embodiment of the invention, each Si layer and each Ge layer in the Si/Ge layer respective have the thickness of 2.1˜3.1 nm.

In one embodiment of the invention, the Si/Ge layer is a repeated structure consisting by a Ge layer and a Si layer, and the repeated structure is deposited for at least once.

In one embodiment of the invention, the second oxide layer has a thickness of 4.2˜6.2 nm.

In one embodiment of the invention, Al₂O₃, Si/Ge and Al₂O₃ are sequentially deposited on the substrate as a laminate structure and then are subject to rapid thermal annealing.

In one embodiment of the invention, the laminate structure of Al₂O₃, Si/Ge and Al₂O₃ are deposited by electron beam evaporation.

In one embodiment of the invention, the conductive layer is an Al layer.

In one embodiment of the invention, a Si layer in the Si/Ge layer provides additional nucleation sites to combine with the Ge layer for adjustment of energy gaps.

### BRIEF DESCRIPTION OF THE DRAWINGS

FIG. 1 is a schematic flow chart of manufacturing a Write-Once-Read-Many-times (WORM) memory according to the invention.

FIG. 2 is a cross-sectional TEM image of Si/Ge nanocrystals embedded in Al₂O₃ according to the present invention.

FIG. 3 is a schematic view of energy bands for a WORM memory device according to the present invention.

FIG. 4 is a schematic view of normalized CV characteristics at 1 MHz at different pulse conditions of a WORM memory device according to the present invention.

FIG. 5A is a schematic view of IV characteristics of a WORM memory device from 0 to +4 at various pulse conditions according to the present invention.

FIG. 5B is a schematic view of IV characteristics of a WORM memory device from 0 to −4 at various pulse conditions according to the present invention.

FIG. 6 is a schematic view of durability of a WORM memory device measured at room temperature and 100° C. according to the present invention.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

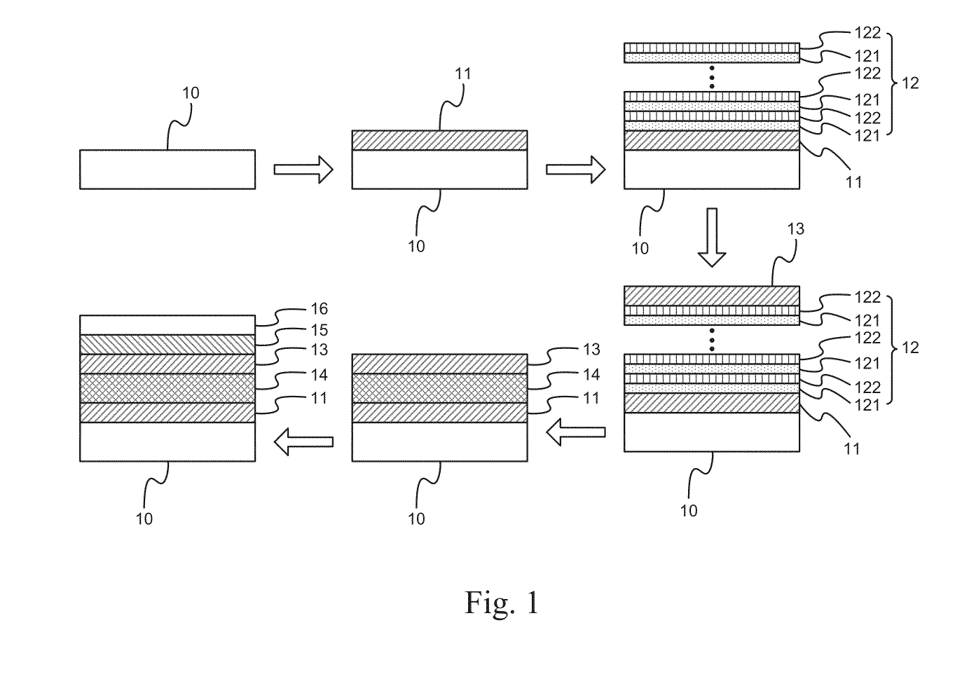

FIG. 1 is a schematic flow chart of manufacturing a Write-Once-Read-Many-times (WORM) memory according to the invention. As shown, the process of manufacturing a Write-Once-Read-Many-times (WORM) memory according to the invention at least includes the following steps:

(A) providing a silicon substrate 10 as a lower electrode;

(B) depositing a first oxide layer 11 on the Si substrate 10;

(C) depositing at least one or more silicon/germanium (Si/Ge) layers 12 on the first oxide layer 11;

(D) depositing a second oxide layer 13 on the at least one or more Si/Ge layers 12;

(E) caning out a rapid thermal annealing (RTA): oxygen (02) is diluted with nitrogen (N2) with the reaction at 600˜800° C. for 80 to 100 seconds; a Si layer 121 in the Si/Ge layer 12 provides additional nucleation sites to combine with the Ge layer 122 for adjustment of energy gaps, so that the Si/Ge layer 12 can form a SiGe nano-crystal structure (SiGe nanocrystals) 14 embedded in the first dioxide layer 11 and the second oxide layer 13; and

(F) depositing a conductive layer 15 on the second oxide layer 13 as an upper electrode to form a WORM memory device. The memory device further includes a protective layer 16 deposited on the conductive layer 15.

The first dioxide layers 11 and the second oxide layer 13 are of high dielectric constant (high-k) non-crystalline material, and can be Al₂O₃. The first oxide layer 11 has the thickness ranging from 5.0 to 7.4 nanometer (nm) The thickness of the second oxide layer 13 is between 4.2˜6.2 nm.

The Si/Ge layer 12 can be a repeated structure consisting by a Si layer 121 and a Ge layer 122 (as shown in FIG. 1), or of a Ge layer and a layer Si layer. The repeated structure is deposited for at least once. The Si layer 121 and the Ge layer 122 in the Si/Ge layer 12 respective have the thickness of 2.1˜3.1 nm.

When the present invention in use, a P-type Si wafer is used as a starting material. In a preferred embodiment, by the electron beam evaporation the Al₂O₃ (6.2 nm) 11, the Si (2.6 nm)/Ge (2.6 nm) 12 and the Al₂O₃ (5.2 nm) 13 are sequentially deposited on the Si substrate 10 as a laminate structure. Subsequently by rapid thermal annealing in a N₂-diluted oxygen environment at 700° C. for 90 seconds (1.0% O₂ per volume), the SiGe nano-crystal structure 14 is formed to be embedded between the Al₂O₃ 11 and 13. Finally, Al conductive layer 15 is deposited as an upper electrode to form the WORM memory device. In addition, in another embodiment, a device with a single Al₂O₃ film of 17.0 nm can be also prepared for investigating the influence of the SiGe nanocrystals on performance of the device.

The WORM memory device of the present invention can be used, in addition for investigating electrical characteristics in the 250 μm×250 μm area, analyzing the composition of the nanocrystals in a transmission electron microscopy (TEM), an electron diffraction pattern, and an energy dispersive analyzer (EDS).

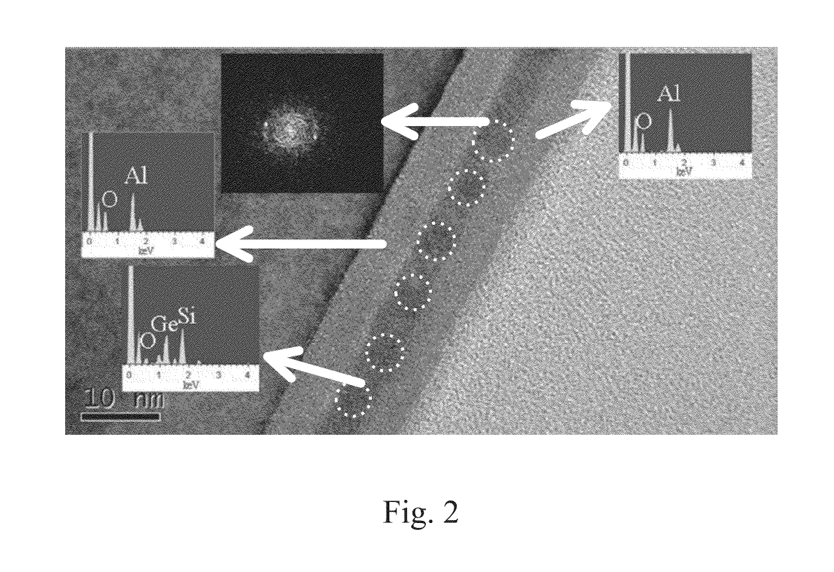

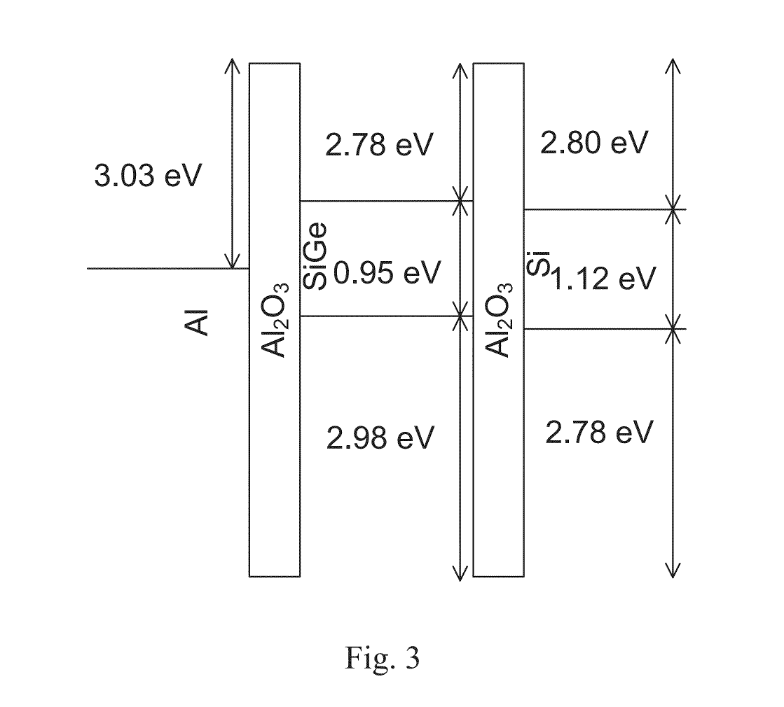

FIG. 2 is a cross-sectional TEM image of Si/Ge nanocrystals embedded in Al₂O₃ according to the present invention. FIG. 3 is a schematic view of energy bands for a WORM memory device according to the present invention. From the sample of annealed Si/Ge layer as shown, it can be found that the surfaces of the nanocrystals are embedded in Al₂O₃, showing silicon and germanium may be blended in the crystallization process of annealing during the nanocrystals are formed. From the location of the nanocrystals shown in the illustration of FIG. 2 and EDS analysis results of the Al₂O₃ bilayer near the nanocrystals, it is also found that Si and Ge can be identified as nanocrystals due to their signals and the composition of SiGe can be proven. Furthermore, Si and Ge signals which are so insignificant that they can be ignored are found in the vicinity of Al₂O₃. Such an image explains that outward diffusion of Si and Ge atoms can be prevented by means of a good diffusion barrier layer of Al₂O₃. The crystalline structure of the nanocrystals is confirmed by electron diffraction patterns shown in the illustration in FIG. 2. “Electrical performance” intends to limit to embedded nanocrystal devices herebelow, except of any other specific description in this specification. The energy band diagram of the embedded nanocrystal device as shown in FIG. 3 explains how the energy band structure can affect the following electrical characteristics.

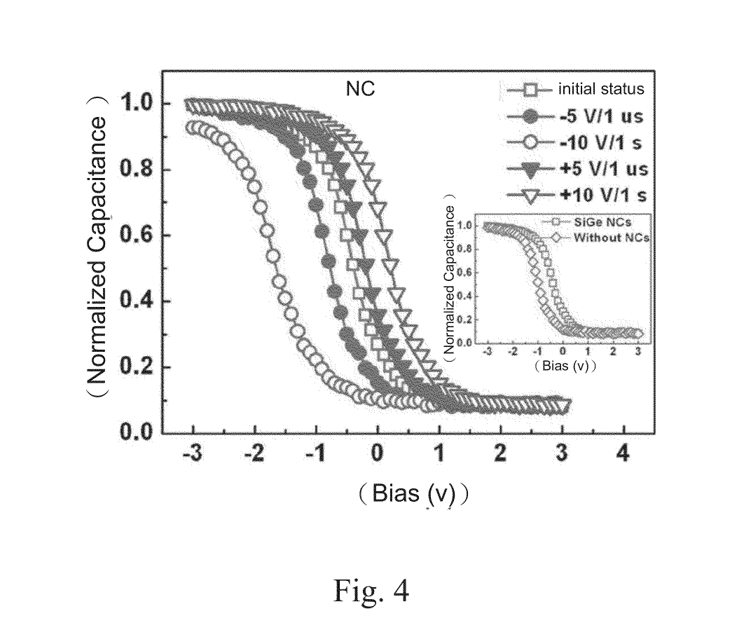

FIG. 4 is a schematic view of normalized CV characteristics at 1 MHz at different pulse conditions of a WORM memory device according to the present invention. As shown, during measuring a central curve indicates that the device is not at initial status where no pulse is applied. When the curve at application of positive or negative pulse respectively shifts to right or to left. The curve shift can be attributed to the influence of the mobile network storage of electrons and holes on the flat-band voltage (V_{FB}). The negative pulses introduce mobile negative charges which will be then stored in the SiGe nanocrystals. The flat-band voltage V_{FB} shifts more obviously, which can be proved by the comparison of capacitance—voltage (CV) curves of the devices having SiGe or not having SiGe at initial status. In the illustration, the device having SiGe nanocrystals has higher flat-band voltage VFB shows the pre-existing negative charges might be formed when Si is blended with Ge.

In fact, the incorporation of oxygen atoms contributing to the formation of oxygen-related defects such as oxygen gap (Oᵢ, O₂ᵢ) and oxygen-vacancy complexes (VO, VO₂) in Si and Ge has been disclosed. In crystalline silicon, the oxygen-vacancy complexes are known to exist in two charge states including single negative and neutral charge states. In addition, the oxygen-vacancy complexes in crystalline germanium have three charge states including double-negative, single-negative, and neutral charge states. After EDS analysis of nanocrystals in the present invention, a relatively weak oxygen signal is obtained, which verifies the diffusion of a small amount of oxygen atoms from Al₂O₃ to the SiGe nanocrystals in the thermal annealing process. Since the oxygen atoms are included in the SiGe nanocrystals, the possibility of forming the oxygen-vacancy complexes is extremely high because the complexes tend to be negatively charged. From the illustration, more positive flat-band voltages V_{FB} of the devices having SiGe nanocrystals can be observed. As shown in FIG. 2, when a negative pulse is applied, the mobile negative charges shift to Si form nanocrystals, and the holes (majority of carriers) are injected into the nanocrystals from the Si substrate is injected. Both are passing through Al₂O₃. The fact is that the potential barrier is thinned are regarded as the tunneling of the holes, resulting in a good hole tunneling. The stored mobile negative charges will effectively improve the energy band diagram. Therefore, the tunneling of the electrons and holes helps large band voltage V_{FB} to move toward the negative direction. On the other hand, due to the stored mobile negative charges in the nanocrystals will effectively improve the local conduction band, and increase the thickness of the potential barrier which is an indicator of electron tunneling, the injection of electrons (minority of carriers) from Si will become not in favor of the tunneling at positive bias and thus might lead to a smaller shift of flat-band voltage V_{FB}. It is noted that the tunneling of electrons and holes means the electrons and holes travel through Si/Al₂O₃ instead of Al/Al₂O₃ interface. This is mainly because that the N₂ annealing process dilutes oxygen while enhances the dielectric integrity in the upper Al₂O₃, causing the tunneling does not easily occur at the Al/Al₂O₃ interface. Furthermore, it is note that after positive or negative pulses are applied to the device having no SiGe nanocrystals, no shift is found in the CV curves, indicating the existence of charges in SiGe nanocrystals instead of Al₂O₃ (not shown).

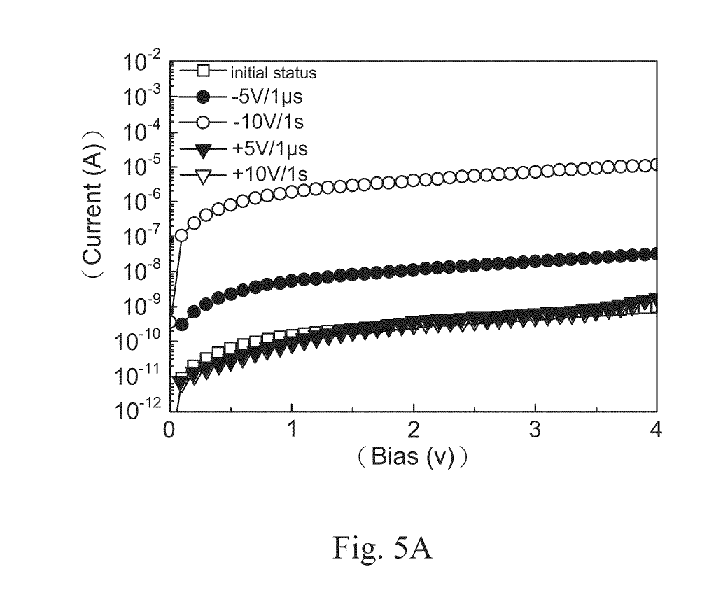

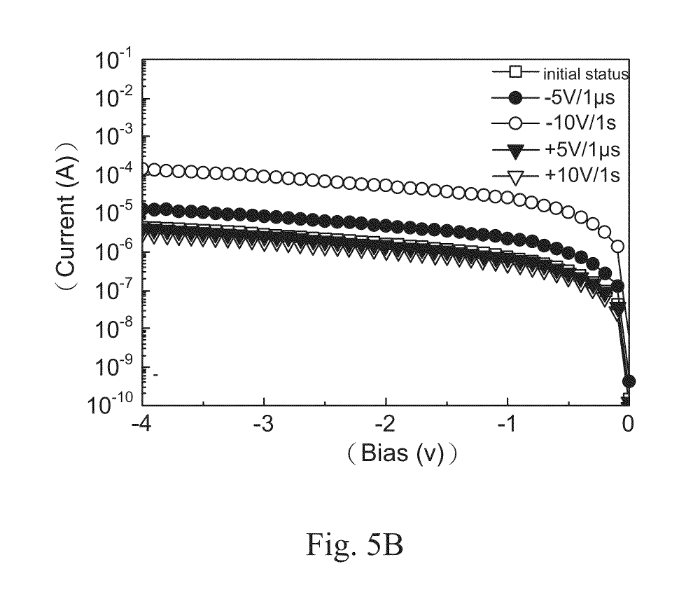

FIG. 5A is a schematic view of IV characteristics of a WORM memory device from 0 to +4 at various pulse conditions according to the present invention. FIG. 5B is a schematic view of IV characteristics of a WORM memory device from 0 to −4 at various pulse conditions according to the present invention. From FIG. 5A, it is known the current—voltage (IV) characteristics of the device at various pulse conditions, measured from 0 to +4 V. A current to be measured includes the electrons (minority of carriers) injected from Si at these measurement conditions. Among these conditions, a minimal difference of currents between the measured moment and the initial status is obtained at application of +10V/1 s. As shown in FIG. 4, in the case that the previously stored negative charges and the injected electronic exist in the nanocrystals of the device, the electronic potential barrier becomes thicker as a positive pulse is applied, inhibiting the electrons from being injected from Si so that the current keeps almost unchanged or even slightly lower than the initial status. In contrast, for the device which −10V/1 s voltage is applied to, the current significantly increased 10₄ times at voltage of +1.5 V compared to the initial status, which means the device has powerful durability in reading and good persistence. It is believed that the programmed state and mainly the thinned potential barrier contribute to the enhanced current level. The holes are stored in the nanocrystals via the network. By lowering the programming voltage and pulse width to −5V/1 μs, the current can be still enhanced 36 times. The change in current is large enough to define the logic “1” and “0” as the application of the memory device. It is confirmed that the device of the present invention can be operated at low power.

IV characteristics the device of the invention at various pulse conditions, measuring from 0 to −4 V, can be found from FIG. 5B compared to FIG. 5A. The current at the measurement conditions mainly consists of the electrons injection from an Al electrode (majority of carriers). Therefore, the current level is much higher than that for devices having different applied pulses to be measured at from 0 to +4 V. However, the change of the device between the application of positive pulse and negative pulse is less apparent than that 0 to +4V. This phenomenon can be explained as follows: The effect of the device is similar to a Schottky diode which has a greater current when applied with a positive bias with scanning at 0 to −4 V. It is reverse bias with low current in the direction of 0 to +4 V. Because of the charges existing in the SiGe nanocrystals, such a reverse bias current is more sensitive to impaired change. The results of the present invention prove that a WORM memory device can read correctly only the positive voltage after the data storage.

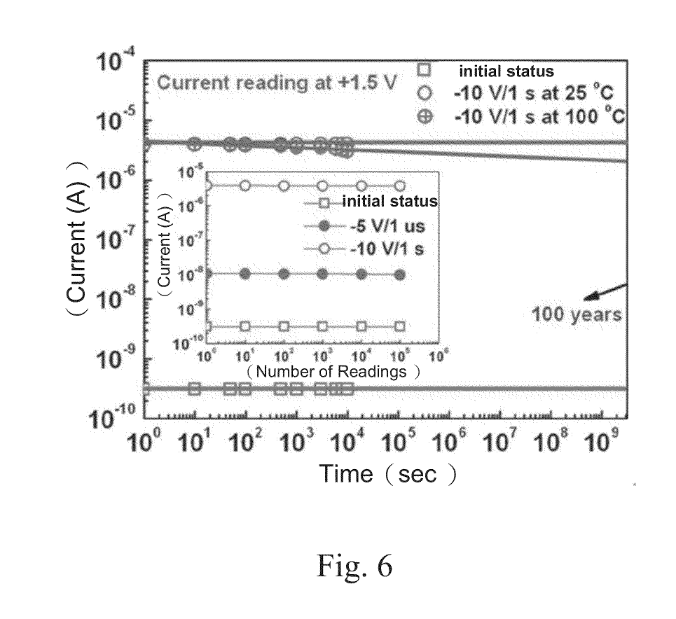

The reading durability is prerequisite for the WORM memory device. The results are shown in an illustration of FIG. 6. Observing up to 10 reading cycles, the loss in current ratio between programming status and the initial status is small.

FIG. 6 is a schematic view of durability of a WORM memory device measured at room temperature and 100° C. according to the present invention. As shown, different from the additional Al nanocrystals-based WORM memory device whose durability will reduce at 100° C., a stable current can be achieved in the present invention, after 10⁴ seconds. Good durability is attributable to the following reasons: (a) charges are stored in SiGe nanocrystals and separated from the Si substrate via Al₂O₃; Because Al₂O₃ has relatively better dielectric integrity than Al-rich Al₂O₃, it can more effectively prevent the loss of charges. (B) The compensation for large valence bands between the SiGe nano-crystal and Al₂O₃ makes easier to maintain the storage of holes in the quantum wells. Thus, by extrapolation, the current ratio between the two statuses basically remains unchanged for over 100 years, showing that the WORM memory device of the present invention is very suitable for long-term data storage. By the use of SiGe nanocrystals embedded Al₂O₃ as an active layer of the WORM memory, the respective thicknesses of the Si layer and the Ge layer can be easily adjusted and thus the performance of the device can further optimize as long as the composition of the SiGe nanocrystals is slightly tuning. Thereby, the high thermal stability, fast writing of the device can be achieved at low operating voltage. Furthermore, the device can have ideal reading life of up to 10⁵ times, excellent durability of more than 100 years, and high reliability of effectively reading data at high temperatures.

The present invention provides SiGe nanocrystals embedded in Al₂O₃ of the WORM memory device. Since Si can provide additional nucleation sites and the energy gaps can be adjusted through combining with Ge so that the high-density SiGe nanocrystals can be formed in the high-k dielectric. The device is stored in the nanocrystals via holes programming at a negative pulse. The current level can increase by 10⁴ times by means of application of −10V/1 s pulse. Even at −5V/1 μs pulse, it still can obtain a large enough current ratio to distinguish the logic states and have good memory characteristics. The compensation for the large valence bands between the nanocrystals and Al₂O₃ contributes to low operating voltage, fast writing, and effectively reading data at high temperature. Moreover, the device offers the ideal reading durability and the persistence at high temperatures to exhibit excellent high temperature performance to ensure its high-temperature operation reliability at high performance so that application programs can be reliably operated. Thereby, the high-performance WORM memory shows the huge potential in application.

In summary, the present invention is a WORM memory and a process of manufacturing thereof, which can effectively improve the shortcomings of the prior art. By the use of SiGe nanocrystals embedded in the Al₂O₃ bilayer as the active layer of the WORM memory to offer high thermal stability, it can achieve the low operating voltage, the fast writing, the ideal reading durability, and the persistence at high temperature, and the highly reliable memory performance for effectively reading data at high temperature. This makes the invention more progressive and more practical in use which complies with the patent law.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

1. A process of manufacturing a Write-Once-Read-Many-times (WORM) memory, at least comprising the following steps:
(A) providing a Si substrate as a lower electrode;
(B) depositing a first oxide layer on the Si substrate;
(C) depositing at least one or more silicon/germanium (Si/Ge) layers on the first oxide layer;
(D) depositing a second oxide layer on the at least one or more Si/Ge layers;
(E) carrying out a rapid thermal annealing (RTA) in an oxygen (O₂) diluted with nitrogen (N₂) atmosphere with the reaction at 600 to 800° C. for 80 to 100 seconds such that the at least one or more Si/Ge layers forms a SiGe nano-crystal structure (SiGe nanocrystals) embedded in the first oxide layer and the second oxide layer; and
(F) depositing a conductive layer on the second oxide layer as an upper electrode.

2. The process of claim 1, further comprising a step of depositing a protective layer on the conductive layer.

3. (canceled)

4. The process of claim 1, wherein the first oxide layers and the second oxide layer are of high dielectric constant (high-k) non-crystalline material, and comprise Al₂O₃.

5. The process of claim 1, wherein the first oxide layer has the thickness ranging from 5.0 to 7.4 nanometer (nm).

6. The process of claim 1, wherein the Si/Ge layer is a repeated structure consisting of an alternating Si layer and a Ge layer and the repeated structure is deposited multiple times.

7. The process of claim 1, wherein each Si layer and each Ge layer in the Si/Ge layer respective have the thickness of 2.1˜3.1 nm.

8. The process of claim 1, wherein the Si/Ge layer is a repeated structure consisting of an alternating Ge layer and a Si layer, and the repeated structure is deposited multiple times.

9. The process of claim 1, wherein the second oxide layer has a thickness of 4.2˜6.2 nm.

10. The process of claim 1, wherein Al₂O₃, Si/Ge and Al₂O₃ are sequentially deposited on the substrate as a laminate structure and then are subject to rapid thermal annealing.

11. The process of claim 10, wherein the laminate structure of Al₂O₃, Si/Ge and Al₂O₃ are deposited by electron beam evaporation.

12. The process of claim 1, wherein the conductive layer is an Al layer.

13. The process of claim 1, wherein a Si layer in the Si/Ge layer provides additional nucleation sites to combine with the Ge layer for adjustment of energy gaps.
